(19) United States
(12) Patent Application Publication
(10) Pub. No.: US 2026/0190521 A1
(43) Pub. Date: Jul. 2, 2026

(54) IMAGE SENSING DEVICE

(71) Applicant: SK hynix Inc., Icheon-si (KR)

(72) Inventor: Kyung Su BYUN, Icheon-si (KR)

(21) Appl. No.: 19/429,835

(22) Filed: Dec. 22, 2025

(30) Foreign Application Priority Data
Dec. 26, 2024 (KR) 10-2024-0197691

(51) Int. Cl. H10F 39/00

(52) U.S. Cl. CPC H10F 39/8037; H10F 39/806; H10F 39/811

(57) ABSTRACT

Provided is an image sensing device which includes a sensing area configured to receive incident light and generate photocharges corresponding to the incident light and a transistor area that is located on one side of the sensing area and that reads out a pixel signal corresponding to the photocharges generated in the sensing area. The sensing area includes a substrate having a first surface on which the incident light is incident and a second surface opposite the first surface and including a photoelectric conversion area configured to convert the incident light into the photocharges, and a first trench guide that is located on the second surface around the photoelectric conversion area and configured to scatter reflected light into the substrate. The reflected light is part of the incident light and transmitted through the substrate.

### PRIORITY CLAIM AND CROSS-REFERENCE TO RELATED APPLICATION

This patent document claims the priority and benefits of Korean Patent Application No. 10-2024-0197691, filed in the Korean Intellectual Property Office on December 26, 2024, the entire contents of which are incorporated herein by reference.

### TECHNICAL FIELD

The technology and implementations disclosed in this patent document generally relate to an image sensing device.

### BACKGROUND

An image sensor converts an optical image into an electrical signal. Recently, with advancements in industries such as computer industry and the communication industry, the demand for image sensors has been increasing in various fields such as digital cameras, camcorders, personal communication systems (PCS), gaming consoles, security cameras, medical micro cameras, and robots.

To obtain a three-dimensional image using an image sensor, not only information about colors but also information about the distance (or, the depth) between a target object and the image sensor is required.

One of the methods of obtaining the information about the distance between the target object and the image sensor is a time-of-flight (TOF) method. The TOF method calculates the distance between the target object and the image sensor by measuring the time it takes for light to be emitted toward the target object and returned after being reflected from the target object.

### SUMMARY

Various implementations of the disclosed technology provide a sensing device for improving photoelectric efficiency.

The technical problems to be solved by the present disclosure are not limited to the aforementioned problems, and any other technical problems not mentioned herein will be clearly understood from the following description by those skilled in the art to which the present disclosure pertains.

In one aspect, an image sensing device is provided to include a sensing area configured to receive incident light and generate photocharges corresponding to the incident light and a transistor area that is located on one side of the sensing area and that reads out a pixel signal corresponding to the photocharges generated in the sensing area. The sensing area includes a substrate having a first surface on which the incident light is incident and a second surface opposite the first surface and including a photoelectric conversion area configured to convert the incident light into the photocharges and a first trench guide that is located on the second surface around the photoelectric conversion area and configured to scatter reflected light into the substrate. The reflected light is part of the incident light and transmitted through the substrate.

In another aspect, an image sensing device is provided to include a substrate layer including a substrate including a first surface and a second surface opposite the first surface and a photoelectric conversion area located within the substrate, a light incident layer located over the first surface and that focuses incident light on the substrate for image sensing at the photoelectric conversion area, and a wiring layer that is located under the second surface and including wiring. The substrate layer further includes a first trench guide that scatters, into the substrate, reflected light incident on the second surface after being reflected from the wiring layer.

### BRIEF DESCRIPTION OF THE DRAWINGS

The above and other objects, features and advantages of the present disclosure will be more apparent from the following detailed description taken in conjunction with the accompanying drawings:

FIG. 1 is a schematic diagram illustrating a configuration of an image sensing device based on some implementations of the disclosed technology.

FIG. 2 is a plan view illustrating a planar structure of one unit pixel in a pixel array of FIG. 1.

FIG. 3A is a sectional view illustrating a cross-section of the pixel array taken along line Y-Y′ in FIG. 2.

FIG. 3B is a sectional view illustrating a cross-section of the pixel array taken along line X-X′ in FIG. 2.

FIG. 4 is a view illustrating a structure of a first trench guide based on some implementations of the disclosed technology.

FIG. 5 is a plan view illustrating a structure of a first trench guide based on some implementations of the disclosed technology.

FIG. 6 is a sectional view illustrating a cross-sectional structure of a unit trench guide of FIG. 5.

FIG. 7 is a view illustrating a structure of a first trench guide based on some implementations of the disclosed technology.

### DETAILED DESCRIPTION

Hereinafter, some embodiments of the present disclosure will be described in detail with reference to the exemplary drawings. In adding the reference numerals to the components of each drawing, it should be noted that the identical or equivalent component is designated by the identical numeral even when they are displayed on other drawings. Further, in describing the embodiment of the present disclosure, a detailed description of well-known features or functions will be ruled out in order not to unnecessarily obscure the gist of the present disclosure.

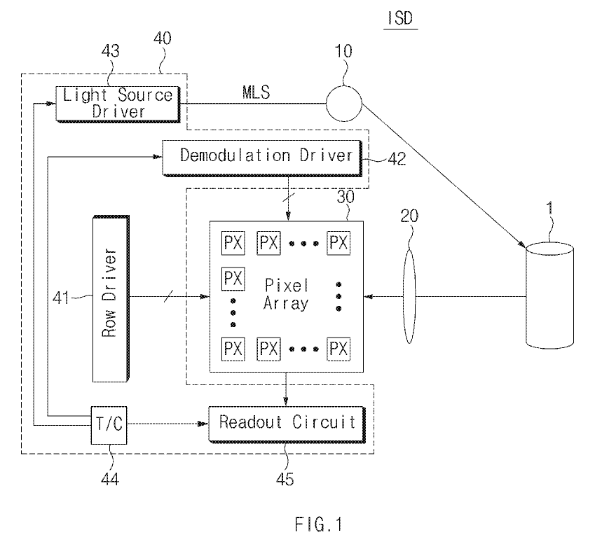

FIG. 1 is a schematic diagram illustrating a configuration of an image sensing device based on some implementations of the disclosed technology.

Referring to FIG. 1, the image sensing device ISD of this embodiment may measure the distance to a target object 1 using the time of flight (TOF) principle. The image sensing device ISD may include a light source 10, a lens module 20, a pixel array 30, and a control block 40.

The light source 10 may emit light to the target object 1 in response to a light modulation signal MLS from the control block 40 as a control signal which is fed into the light source 10 to cause light modulation in the light emitted by the light source 10 for illuminating the target object 1. The light source 10 may be or include a laser diode (LD) or a light emitting diode (LED) that emits light in a specific wavelength band (e.g., infrared light, near-infrared light, or visible light), a near-infrared laser (NIR), a point light source, a monochromatic light source with a combination of a white lamp and a monochromator, or a combination of other laser light sources. For example, the light source 10 may emit infrared light having a wavelength of 800 nm to 1000 nm. For convenience of description, only one light source 10 is illustrated in FIG. 1. However, a plurality of light sources may be arranged around the lens module 20.

The lens module 20 may collect light reflected from the target object 1 and may focus the collected reflected light on unit pixels PX of the pixel array 30. For example, the lens module 20 may include a focusing lens having a glass or plastic surface or another cylindrical optical element. The lens module 20 may include a plurality of lenses aligned with an optical axis as the center.

The pixel array 30 may include the plurality of unit pixels PX arranged in a two-dimensional structure (e.g., continuously arranged in a column direction and a row direction). The unit pixel PX may be a minimum unit in which the same shape is repeatedly arranged on the pixel array 30.

Each unit pixel PX may be formed on a semiconductor substrate and may photoelectrically convert the light incident through the lens module 20 to generate and output a pixel signal that is an electric signal corresponding to the incident light. The pixel signal may be a signal representing the distance to the target object 1 rather than a signal representing the color of the target object 1. Each unit pixel PX may be a current-assisted photonic demodulator (CAPD) type pixel that detects photocharges (e.g., electrons) generated within the substrate by the incident light using a potential difference of an electric field.

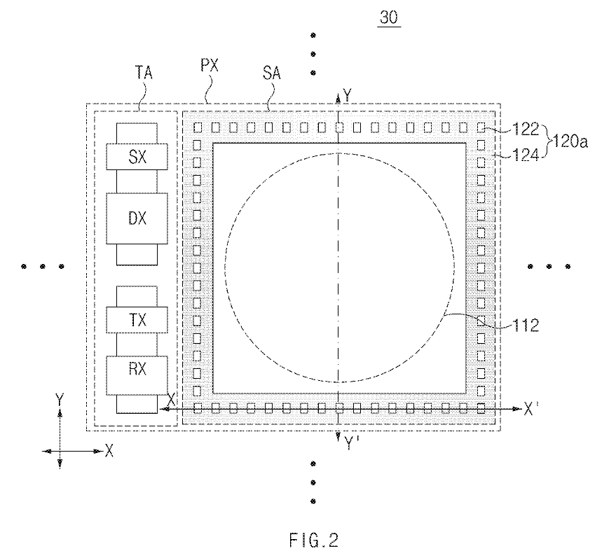

Each unit pixel PX may include a first trench guide formed on a second surface (a rear surface) of the semiconductor substrate and a second trench guide formed on a first surface (a front surface) that is opposite the second surface. The structure and function of the first and second trench guides will be described below with reference to FIG. 2 and the following drawings.

The control block 40 may control the light source 10 to emit light to the target object 1 and may drive the unit pixels PX of the pixel array 30 to process pixel signals corresponding to the light reflected from the target object 1 to measure the distance to the surface of the target object 1.

The control block 40 may include a row driver 41, a demodulation driver 42, a light source driver 43, a timing controller 44, and a readout circuit 45.

The row driver 41 and the demodulation driver 42 may be collectively referred to as a control circuit.

The control circuit may drive the unit pixels PX of the pixel array 30 in response to a timing signal output from the timing controller 44. For example, the control circuit may generate control signals capable of selecting and controlling at least one row line among a plurality of row lines. The control signals may include a demodulation control signal that generates a hole current in the substrate, a reset signal that controls a reset transistor, a transfer signal that controls a transfer transistor for the transfer of photocharges accumulated in a detection node, and a selection signal that controls a selection transistor. The row driver 41 may generate the reset signal, the transfer signal, and the selection signal, and the demodulation driver 42 may generate the demodulation control signal.

The light source driver 43 may generate the light modulation signal MLS capable of driving the light source 10 based on the control of the timing controller 44. The light modulation signal MLS may be a signal modulated at a predetermined frequency.

The timing controller 44 may generate a timing signal to control operations of the row driver 41, the demodulation driver 42, the light source driver 43, and the readout circuit 45.

The readout circuit 45 may process pixel signals output from the pixel array 30 under the control of the timing controller 44 to generate pixel data in the form of a digital signal. To achieve this, the readout circuit 45 may include a correlated double sampler (CDS) for performing correlated double sampling on the pixel signals output from the pixel array 30.

Furthermore, the readout circuit 45 may include an analog-to-digital converter for converting output signals from the correlated double sampler into digital signals. In addition, the readout circuit 45 may include a buffer circuit for temporarily storing pixel data output from the analog-to-digital converter and outputting the pixel data to the outside under the control of the timing controller 44.

The light source 10 may emit modulated light modulated at a predetermined frequency toward the target object 1, and the pixel array 30 may detect the modulated light reflected from the target object 1 (e.g., incident light) and may generate depth information for each unit pixel PX. There is a time delay between the modulated light and the incident light depending on the distance between the image sensing device ISD and the target object 1. The time delay appears as a phase difference between a signal generated by the image sensing device ISD and the light modulation signal MLS that controls the light source 10. An image processor (not illustrated) may generate a depth image including depth information for each unit pixel PX by calculating the phase difference appearing in the signal output from the image sensing device ISD.

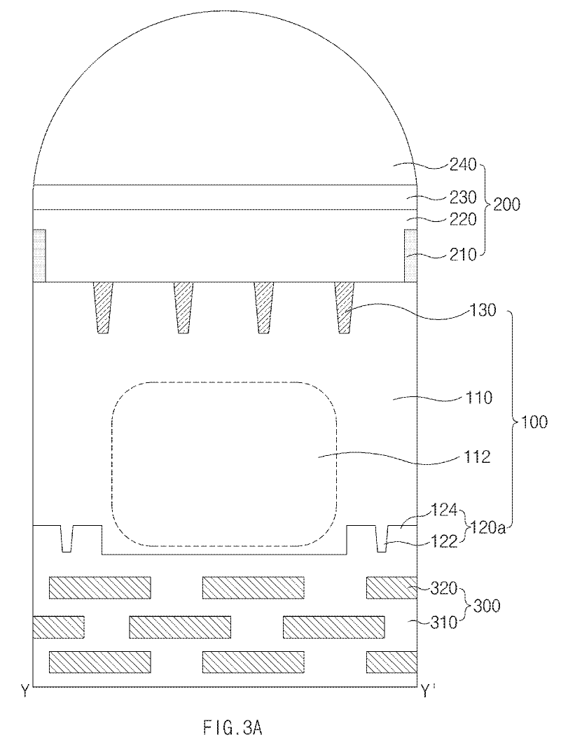

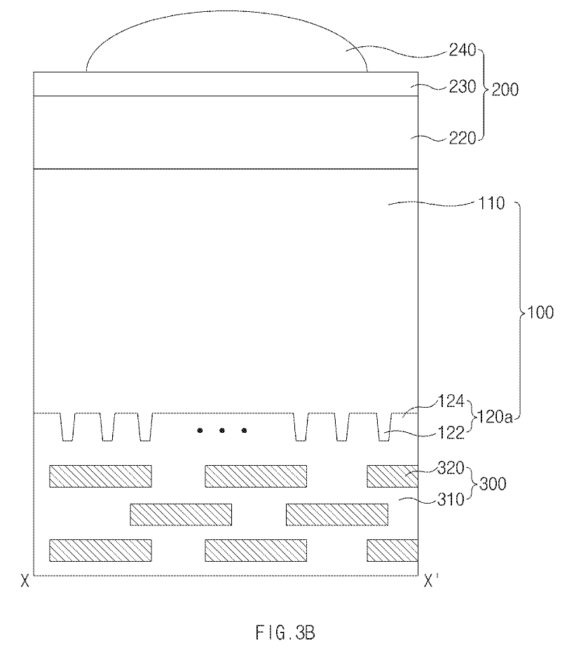

FIG. 2 is a plan view illustrating a planar structure of one unit pixel in the pixel array of FIG. 1, and FIGS. 3A and 3B are sectional views illustrating cross-sections of the pixel array taken along lines Y-Y′ and X-X′ in FIG. 2, respectively.

FIG. 2 may be a view illustrating the unit pixel viewed from above the second surface of the substrate.

Referring to FIGS. 2, 3A, and 3B, each unit pixel PX may include a sensing area SA and a transistor area TA disposed one side of the sensing area SA. In the example, the pixel array 30 may include a substrate layer 100 in which unit pixels PXs are formed, a light incident layer 200 formed over the substrate layer 100, and a wiring layer 300 formed under the substrate layer 100.

The sensing area SA may convert incident light to generate photocharges corresponding to the incident light. The sensing area SA may be formed in the substrate layer 100 and may include a substrate 110, a photoelectric conversion area 112, a first trench guide 120a, and a second trench guide 130. In the example as shown in FIGS. 2 to 3B, the first trench guide 120a and the second trench guide 130 are disposed on the opposite surfaces of the substrate 110, respectively, and function to improve the photoelectric efficiency.

The substrate 110 may include a semiconductor substrate having a first surface and a second surface opposite the first surface. The first surface may be a surface in contact with the light incident layer 200, and the second surface may be a surface in contact with the wiring layer 300. The substrate 110 may be, for example, a silicon single crystal substrate. The substrate 110 may be a P-type or N-type bulk substrate, a substrate in which a P-type or N-type epitaxial layer is grown on a P-type bulk substrate, or a substrate in which a P-type or N-type epitaxial layer is grown on an N-type bulk substrate.

The photoelectric conversion area 112 may be formed within the substrate 110 and may convert light to generate photocharges. The photoelectric conversion area 112 may be located in the central portion of the sensing area SA and may include N-type impurities.

The first trench guide 120a can improve the photoelectric efficiency of the unit pixel by scattering, into the substrate 110, the reflected light that returns to the substrate 110 after being reflected from the wiring layer 300, wherein the reflected light is part of the incident light that entered through the light incident layer 200 and transmitted through the substrate 110. For example, when the image sensing device ISD of this embodiment is a sensing device that senses infrared rays (IR), infrared rays have a longer wavelength than visible light and therefore are more likely to transmit through the substrate 110, and light that transmits through the substrate 110 may be reflected by metal wiring 320 or other reflection structures in the wiring layer 300 and may return to the substrate 110. The first trench guide 120a may scatter, into the substrate 110, the reflected light that returns to the second surface of the substrate 110 after being reflected from the wiring layer 300, among the incident light, thereby enabling the light to remain within the substrate 110 for a long time and thus improving the photoelectric efficiency.

The first trench guide 120a may include a plurality of pins 122 protruding from a surface of the substrate 110 and a trench 124 surrounding each of the plurality of pins 122. For example, the first trench guide 120a may be formed in a shape in which the second surface of the substrate 110 is etched by a certain depth such that the plurality of pins 122 protruding in a pillar shape from the bottom surface of the trench 124 are located to be spaced apart from each other. The reflected light that travels toward the first trench guide 120a after being reflected from the wiring layer 300 may be scattered by the pins 122.

The trench 124 may extend in a first direction (e.g., an X-direction) and a second direction (e.g., a Y-direction) crossing the first direction to have the same width in the edge area of the sensing area SA. For example, the trench 124 may be formed in the shape of a single square band in which first trench areas extending in the first direction in the edge area of the sensing area SA (trench areas located on the upper and lower sides of the photoelectric conversion area 112 in FIG. 2) and second trench areas extending in the second direction and having the same width as the first trench areas (trench areas located on the left and right sides of the photoelectric conversion area 112 in FIG. 2) are connected with each other to surround the photoelectric conversion area 112. The plurality of pins 122 may be continuously arranged in a line in the first direction and the second direction along the center line of the trench 124. However, without being limited thereto, the first trench guide 120a may be arranged in various ways for optimal efficiency.

Although FIG. 2 illustrates an example that the pins 122 are formed in a square pillar shape, the pins 122 may be formed in various pillar shapes such as a cylinder and a hexagonal pillar. In addition, although FIG. 2 illustrates an example that the pins 122 are arranged in a line in the first direction and the second direction, the pins 122 may be arranged in a plurality of rows along the center line of the trench 124 in the first direction and the second direction depending on the size of the pins 122 and the width of the trench 124.

An insulating material (e.g., an oxide film) having a refractive index different from that of the substrate 110 may gap-fill the trench 124. For example, an interlayer insulating film 310 of the wiring layer 300 may gap-fill the trench 124 of the first trench guide 120a.

The first trench guide 120a may be formed on a partial area of the second surface of the substrate 110 that does not overlap the photoelectric conversion area 112. For example, on the second surface of the substrate 110, the first trench guide 120a may be formed in the edge area of the sensing area SA in a band shape surrounding the photoelectric conversion area 112. The first trench guide 120a may reflect and scatter light that does not travel toward the photoelectric conversion area 112 but travels toward the edge area of the sensing area SA, among the light that returns to the substrate 110 after being reflected from the wiring layer 300, thereby increasing the amount of light introduced into the photoelectric conversion area 112.

The second trench guide 130 may be formed on the first surface of the substrate 110 and may focus, on the photoelectric conversion area 112, light incident on the first surface of the substrate 110 through the light incident layer 200. The second trench guide 130 may include a structure in which an insulating material (e.g., an oxide film) having a refractive index different from that of the substrate 110 gap-fills trenches etched by a certain depth from the first surface of the substrate 110.

The width and depth of the second trench guide 130 may be adjusted to increase the angle of refraction of light transmitting through the second trench guide 130, thereby enabling the corresponding light to be well focused on the photoelectric conversion area 112. In addition, the second trench guide 130 may allow light entering the trench to travel downward while being continuously reflected from the inner wall of the trench, thereby increasing the travel path of the incident light and thus enabling light having a long wavelength to be well focused on the photoelectric conversion area 112 even though the corresponding light is incident.

The transistor area TA may be located on one side of the sensing area SA in the substrate layer 100 and may include pixel transistors for reading out a pixel signal corresponding to photocharges generated in the sensing area SA. For example, the pixel transistors may include a transfer transistor TX that controls the transfer of photocharges accumulated in the photoelectric conversion area 112, a drive transistor DX that amplifies a signal corresponding to the transferred photocharges, a selection transistor SX that outputs a signal output from the drive transistor DX to a signal line, and a reset transistor RX that initializes the unit pixel PX to a pixel voltage. The pixel transistors may be formed on the second surface of the substrate 110.

The light incident layer 200 may be formed over the substrate layer 100 to focus incident light incident after being reflected from the target object 1 on the substrate 110. For example, the light incident layer 200 may be located in contact with the first surface of the substrate 110 and may focus the incident light on the second trench guide 130. The light incident layer 200 may include an optical filter 220, an anti-reflection film 230, and a micro lens 240.

The optical filter 220 may be formed over the first surface of the substrate 110 and may selectively transmit light in a specific wavelength band (e.g., near-infrared light or infrared light) among the incident light. A grid structure 210 may be formed between the optical filters 220 corresponding to adjacent unit pixels to prevent crosstalk of the incident light. The micro lens 240 may be formed in a hemispherical shape over the optical filter 220 and may increase light gathering power for the incident light to improve light receiving efficiency. The anti-reflection film 230 may be formed under the micro lens 240 to prevent diffuse reflection of the incident light. The anti-reflection film 230 may serve as a planarization layer that removes steps caused by the optical filters 220.

The wiring layer 300 may be formed under the substrate layer 100. The wiring layer 300 may be located in contact with the second surface of the substrate 110. The wiring layer 300 may include the interlayer insulating film 310 and the metal wiring 320 stacked in a plurality of layers within the interlayer insulating film 310. The interlayer insulating film 310 may be formed in a structure in which a plurality of insulating films are stacked. The interlayer insulating film 310 may include at least one of an oxide film and a nitride film. The metal wiring 320 may include wiring that transmits a pixel signal read out from the transistor area TA of the unit pixel PX and control signals required for generating the pixel signal. The metal wiring 320 may include at least one of aluminum (Al), copper (Cu), or tungsten (W).

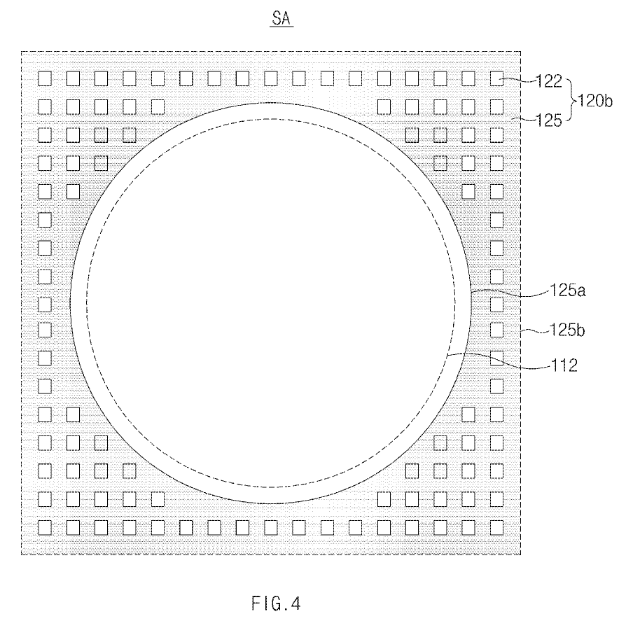

FIG. 4 is a view illustrating a structure of a first trench guide based on some implementations of the disclosed technology.

Referring to FIG. 4, the first trench guide 120b may be formed to entirely cover the outer portion around the photoelectric conversion area 112 in the sensing area SA.

In the first trench guide 120a of FIG. 2 described above, the trench 124 extends in the first direction and the second direction to have the same width in the edge area of the sensing area SA. Unlike the first trench guide 120a of FIG. 2, a trench 125 of FIG. 4 may be formed to surround the photoelectric conversion area 112 while entirely covering the outer area around the photoelectric conversion area 112. This outer area extends from the edge area of the sensing area SA to the area adjacent to the photoelectric conversion area 112. In this case, pins 122 may be evenly distributed within the trench 125. For example, the trench 125 may be located adjacent to the photoelectric conversion area 112 to surround the photoelectric conversion area 112 along the outer line of the photoelectric conversion area 112 on the second surface of the substrate 110, and the pins 122 may be entirely evenly distributed within the trench 125 so as to be spaced apart from each other at a certain interval.

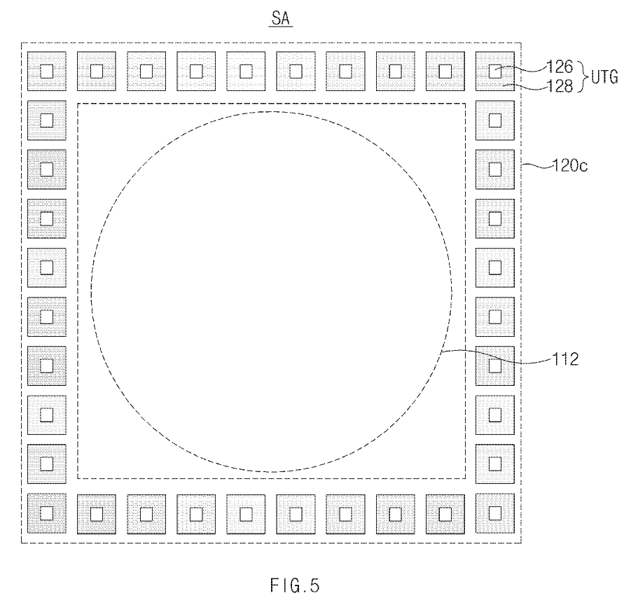

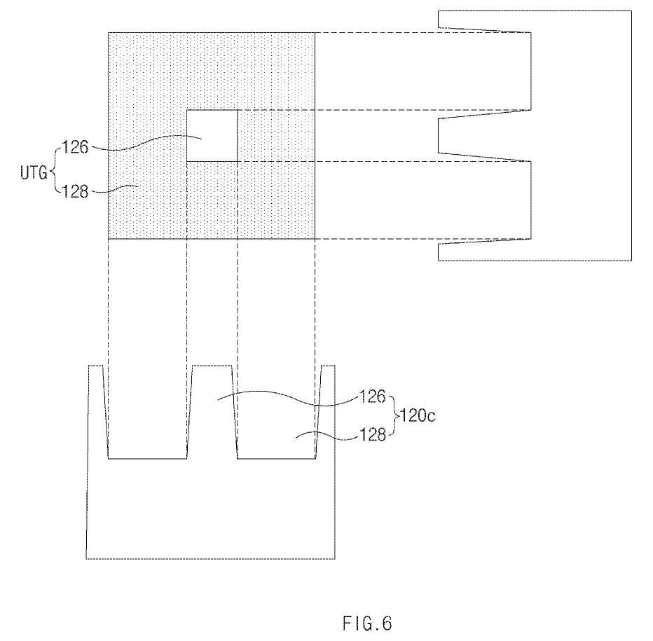

FIG. 5 is a plan view illustrating a structure of a first trench guide based on some implementations of the disclosed technology, and FIG. 6 is a sectional view illustrating a cross-sectional structure of a unit trench guide of FIG. 5.

Referring to FIGS. 5 and 6, the first trench guide 120c may include a plurality of unit trench guides UTG arranged to surround the photoelectric conversion area 112. Each unit trench guide UTG may include a pin 126 and a trench 128 surrounding the pin 126. The pin 126 may be located at the center of the corresponding trench 128. Unlike the first trench guide 120c with multiple pins formed inside the trench as shown in FIG. 2, each individual unit trench guide UTG is a self-contained structure where a single pin 126 is located at a corresponding trench 128.

The plurality of unit trench guides UTG may be arranged to be spaced apart from each other at a certain interval in the first direction and the second direction in the edge area of the sensing area SA. For example, the plurality of unit trench guides UTG may be arranged in the edge area of the sensing area SA in a band shape surrounding the photoelectric conversion area 112.

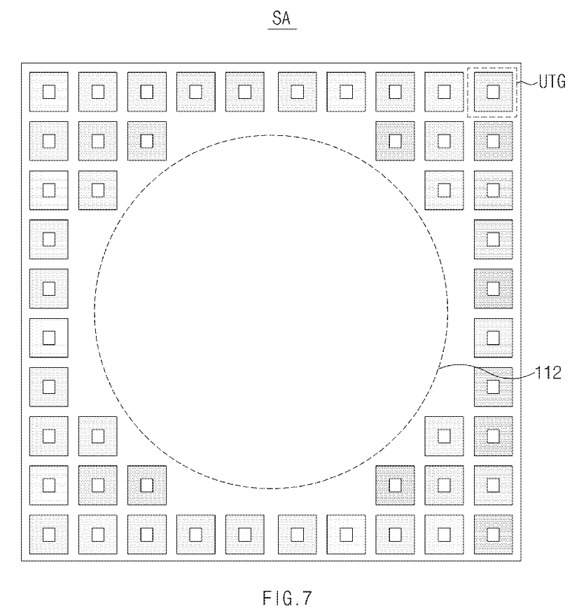

FIG. 7 is a view illustrating a structure of a first trench guide based on some implementations of the disclosed technology.

Referring to FIG. 7, unit trench guides UTG may be formed to be entirely distributed in the area where the photoelectric conversion area 112 is not formed in the sensing area SA. For example, in FIG. 6 described above, the unit trench guides UTG are formed to be arranged in a line in the first direction and the second direction in the edge area of the sensing area SA, but in FIG. 7, the unit trench guides UTG may be evenly disposed to entirely cover the area that does not overlap the photoelectric conversion area 112 in the sensing area SA.

As described above, the embodiments of the present disclosure enable the incident light to remain within the substrate for a long time, thereby improving the photoelectric efficiency of the image sensing device.

Hereinabove, although the present disclosure has been described with reference to exemplary embodiments and the accompanying drawings, it should be understood that numerous modifications or variations to the disclosed embodiments and other embodiments can be devised based on what is described and/or illustrated in this patent document.

What is claimed is:

1. An image sensing device, comprising:
a sensing area configured to receive incident light and generate photocharges corresponding to the incident light; and
a transistor area located on one side of the sensing area and configured to read out a pixel signal corresponding to the photocharges generated in the sensing area,
wherein the sensing area includes:
a substrate having a first surface on which the incident light is incident and a second surface opposite the first surface, the substrate including a photoelectric conversion area configured to convert the incident light into the photocharges; and
a first trench guide located on the second surface around the photoelectric conversion area and configured to scatter reflected light into the substrate, the reflected light being a part of the incident light and transmitted through the substrate.

2. The image sensing device of claim 1, wherein the sensing area further includes a second trench guide located on the first surface and configured to focus the incident light on the photoelectric conversion area.

3. The image sensing device of claim 1, wherein the first trench guide includes:
a trench; and
a plurality of pins located to be spaced apart from each other and configured to protrude in a pillar shape from a bottom surface of the trench.

4. The image sensing device of claim 3, wherein the trench is located in an edge area of the sensing area and has a shape of a band in which first trench areas configured to extend in a first direction and second trench areas configured to extend in a second direction crossing the first direction are connected with each other to surround the photoelectric conversion area, the second trench areas having a same width as the first trench areas.

5. The image sensing device of claim 4, wherein the plurality of pins are arranged in at least a line in the first direction and the second direction along a center line of the trench.

6. The image sensing device of claim 3, wherein the trench entirely covers an outer portion around the photoelectric conversion area in the sensing area.

7. The image sensing device of claim 6, wherein the plurality of pins are entirely evenly distributed to be spaced apart from each other at a certain interval within the trench.

8. The image sensing device of claim 1, wherein the first trench guide includes a plurality of unit trench guides arranged to be spaced apart from each other in a first direction and a second direction crossing the first direction to surround the photoelectric conversion area.

9. The image sensing device of claim 8, wherein the plurality of unit trench guides are arranged in a line in the first direction and the second direction in an edge area of the sensing area.

10. The image sensing device of claim 8, wherein the plurality of unit trench guides are arranged to entirely cover an outer portion around the photoelectric conversion area in the sensing area.

11. The image sensing device of claim 8, wherein each of the plurality of unit trench guides includes:
a pin; and
a trench configured to surround the pin.

12. The image sensing device of claim 1, further comprising:
a light incident layer located on the first surface and configured to focus the incident light on the substrate; and
a wiring layer located under the second surface, the wiring layer including wiring configured to transmit the pixel signal read out from the transistor area.

13. An image sensing device, comprising:
a substrate layer including a substrate including a first surface and a second surface opposite the first surface and a photoelectric conversion area located within the substrate;
a light incident layer located over the first surface and configured to focus incident light on the substrate; and
a wiring layer located under the second surface and including wiring,
wherein the substrate layer further includes a first trench guide configured to scatter, into the substrate, reflected light incident on the second surface after being reflected from the wiring layer.

14. The image sensing device of claim 13, wherein the substrate layer further includes a second trench guide located on the first surface and configured to focus the incident light on the photoelectric conversion area.

15. The image sensing device of claim 13, wherein the first trench guide is located on the second surface to be in contact with the wiring layer.

16. The image sensing device of claim 13, wherein the first trench guide includes:
a trench formed to surround the photoelectric conversion area; and
a plurality of pins located to be spaced apart from each other within the trench and configured to protrude in a pillar shape from a bottom surface of the trench.

17. The image sensing device of claim 16, wherein the trench has a shape of a band in which first trench areas configured to extend in a first direction and second trench areas configured to extend in a second direction crossing the first direction to have a same width as the first trench areas are connected with each other to surround the photoelectric conversion area.

18. The image sensing device of claim 16, wherein the trench is located on the second surface to surround the photoelectric conversion area along an outer line of the photoelectric conversion area.

19. The image sensing device of claim 13, wherein the first trench guide includes a plurality of unit trench guides arranged to be spaced apart from each other in a first direction and a second direction crossing the first direction to surround the photoelectric conversion area.

20. The image sensing device of claim 19, wherein each of the plurality of unit trench guides includes:
a pin; and
a trench configured to surround the pin.
